(19) United States
(12) Patent Application Publication
(10) Pub. No.: US 2015/0035032 A1
(43) Pub. Date: Feb. 5, 2015

(54) NONVOLATILE SEMICONDUCTOR MEMORY DEVICE INCLUDING MEMORY CELL ARRAY WITH PSEUDO SEPARATE SOURCE LINE STRUCTURE

(71) Applicants: Dong-Seok KANG, Seoul (KR); Chan-Kyung KIM, Hwaseong-si (KR)

(72) Inventors: Dong-Seok KANG, Seoul (KR); Chan-Kyung KIM, Hwaseong-si (KR)

(21) Appl. No.: 14/310,114

(22) Filed: Jun. 20, 2014

(30) Foreign Application Priority Data
Aug. 5, 2013 (KR) 10-2013-0092687

(51) Int. Cl. H01L 27/22

(52) U.S. Cl. CPC H01L 27/228
USPC 257/295

(57) ABSTRACT

A memory cell array of a nonvolatile semiconductor memory device is provided which includes a first memory cell including a first variable resistance element and a first access transistor connected to each other, and having a first node connected to a first bit line and one end of the first variable resistance element and a second node connected to a second bit line and one end of the first access transistor; and a second memory cell including a second variable resistance element and a second access transistor connected to each other, and having a first node connected to the second bit line and one end of the second variable resistance element and a second node connected to one end of the second access transistor, wherein the first and second access transistors are connected to first and second word lines, respectively.

### CROSS-REFERENCE TO RELATED APPLICATIONS

This U.S. non-provisional patent application claims the benefit of priority under 35 U.S.C. §119 to Korean Patent Application No. 10-2013-0092687 filed Aug. 5, 2013, in the Korean Intellectual Property Office, the entire contents of which are hereby incorporated by reference.

### BACKGROUND

Embodiments of the disclosure described herein relate to a semiconductor memory device, and more particularly, relate to a memory cell array suitable for a nonvolatile semiconductor memory device such as a resistive memory.

Semiconductor memory devices are widely used for electronic systems that store data. Semiconductor memory devices may be divided into nonvolatile semiconductor memory devices and volatile semiconductor memory devices. Volatile semiconductor memory devices such as an SRAM, a DRAM, etc. lose their stored data when a power is interrupted.

In contrast, nonvolatile semiconductor memory devices such as an EEPROM, a magnetic RAM (MRAM), etc. may retain their stored data even when a power is interrupted. Thus, nonvolatile semiconductor memory devices are typically used to retain data regardless of power failure or power interruption.

In a nonvolatile semiconductor memory device, for example, a spin transfer torque magneto resistive random access memory (STT-MRAM), a chip size and a write voltage level may be variably decided according to a structure where source lines are arranged. Thus, the number of source lines arranged may need to be minimized to reduce a chip size.

In a nonvolatile semiconductor memory device having a common source line structure, an overhead of a chip size may be relatively small, while a high level of write voltage may be needed. Also, the common source line structure may be disadvantageous in terms of a repair operation for replacing defective memory cells with spare memory cells.

A nonvolatile semiconductor memory device having a separate source line structure is configured such that a source line is provided to each bit line. This means that an overhead of a chip size in this type of device may be relatively large.

### SUMMARY

One aspect of example embodiments is directed to provide a memory cell array of a nonvolatile semiconductor memory device which comprises a first memory cell including a first variable resistance element and a first access transistor connected to each other, and having a first node connected to a first bit line and one end of the first variable resistance element and a second node connected to a second bit line and one end of the first access transistor; and a second memory cell including a second variable resistance element and a second access transistor connected to each other, and having a first node connected to the second bit line and one end of the second variable resistance element and a second node connected to one end of the second access transistor, wherein the first and second access transistors are connected to first and second word lines, respectively.

In exemplary embodiments, each of the first and second memory cells is a spin transfer torque magneto resistive random access memory (STT-MRAM) cell including an access transistor and each of the first and second variable resistance elements is a magnetic tunnel junction (MTJ) element.

In exemplary embodiments, the second node of the second memory cell is a node connected to the first bit line.

In exemplary embodiments, the first and second bit lines extend in a first direction, and are spaced apart in a second direction perpendicular to the first direction, and the first and second memory cells are arranged diagonally with respect to each other and the first and second directions.

In exemplary embodiments, the first memory cell and the second memory cell are arranged to be adjacent to each other along the second direction on the basis of the second bit line.

In exemplary embodiments, the first bit line is used as a bit line when the first memory cell is accessed and the second bit line is used as a bit line when the second memory cell is accessed.

Another aspect of example embodiments is directed to provide a memory cell array of a nonvolatile semiconductor memory device which comprises a first memory cell having a first node connected to a first bit line and a second node connected to a second bit line; and a second memory cell having a first node connected to the second bit line and a second node connected to a third bit line, wherein first and second selection transistors of the first and second memory cells are connected to different word lines, respectively; and wherein the third bit line acts as a source line when the second memory cell is accessed and the second bit line acts as a source line when the first memory cell is accessed.

In exemplary embodiments, each of the first and second memory cells is an STT-MRAM cell including an access transistor functioning as a selection transistor and an MTJ element.

In exemplary embodiments, the first node of the first memory cell is a node connected to one end of the MTJ element and the second node of the first memory cell is a node connected to one end of the first selection transistor.

In exemplary embodiments, the first node of the second memory cell is a node connected to one end of the MTJ element and the second node of the second memory cell is a node connected to one end of the second selection transistor.

In exemplary embodiments, the first memory cell and the second memory cell are arranged to be adjacent to each other along the second direction on the basis of the second bit line.

In exemplary embodiments, the first bit line is used as a bit line when the first memory cell, and the second bit line is used as a bit line when the second memory cell is accessed.

In exemplary embodiments, the first bit line acts as a dummy bit line not participating in an access operation when the second memory cell is accessed.

Still another aspect of example embodiments is directed to provide a memory cell array of a nonvolatile semiconductor memory device which comprises a first set of memory cells arranged in a first direction of the memory cell array, each memory cell including a first variable resistance element and a first access transistor connected to each other and having a first node connected to a first bit line and one end of the first variable resistance element, and a second node connected to a second bit line and a first source/drain of the first access transistor; and a second set of memory cells arranged in the first direction, each memory cell including a second variable resistance element and a second access transistor connected to each other and having a first node connected to the second bit line and one end of the second variable resistance element, and a second node connected to a first source/drain of the second access transistor, wherein each memory cell of the first and second sets of memory cells is connected to respective word lines each arranged in a second direction perpendicular to the first direction; and wherein the second bit line acts as a source line when the first group of memory cells is accessed and the second bit line acts as a bit line when the second group of memory cells is accessed.

In exemplary embodiments, each memory cell of the first and second groups of memory cells is an STT-MRAM cell including an MTJ element.

In exemplary embodiments, in the first group of memory cells, the first node is a node connected to one end of the MTJ element and the second node is a node connected to the other end of the MTJ element; and wherein in the second group of memory cells, the first node is a node connected to one end of the MTJ element and the second node is a node connected to the other end of the MTJ element through a corresponding selection transistor.

In exemplary embodiments, the first group of memory cells and the second group of memory cells are arranged between the first bit line and the second bit line to be adjacent to each other in a zigzag shape along a bit line direction.

In exemplary embodiments, the first group of memory cells and the second group of memory cells are arranged to be adjacent to each other along a word line direction on the basis of the second bit line.

In exemplary embodiments, an access to the second group of memory cells is inhibited when the first group of memory cells is accessed.

In exemplary embodiments, the first bit line is used as a bit line when the first group of memory cells is accessed and the second bit line is used as a bit line when the second group of memory cells is accessed.

In exemplary embodiments, a respective MTJ element is connected in common to two selection transistors such that when one selection transistor operates the other selection transistor does not operate; and wherein although the other selection transistor operates, a voltage across an MTJ is equal.

A further aspect of example embodiments is directed to provide a nonvolatile semiconductor memory device which comprises a memory cell array including resistive memory cells and first and second reference memory cells; and a read/write circuit, wherein the memory cell array comprises a first group of memory cells arranged in a first direction and each memory cell having a first node connected to a first bit line and a second node connected to a second bit line; and a second group of memory cells arranged in the first direction and each memory cell having a first node connected to the second bit line and a second node connected to a third bit line, wherein each group of the first and second groups of memory cells are connected to different word lines, respectively; and wherein the third bit line acts as a source line when the second group of memory cells is accessed and the second bit line acts as a source line when the first group of memory cells is accessed.

In exemplary embodiments, each of the resistive memory cells is an STT-MRAM cell including an access transistor and an MTJ element.

In exemplary embodiments, the first and second reference memory cells are implemented by memory cells having the same type as those of the resistive memory cells.

In exemplary embodiments, the first reference memory cell has a resistance value of the resistive memory cell having a first resistance state and the second reference memory cell has a resistance value of the resistive memory cell having a second resistance state different from the first resistance state.

In exemplary embodiments, the first memory cell and the second memory cell are arranged to be adjacent to each other along a word line direction on the basis of the second bit line.

In exemplary embodiments, the first bit line acts as a bit line when the first memory cell is accessed, the second bit line acts as a bit line when the second memory cell is accessed, and the first bit line acts as a dummy bit line, not participating in an access operation, when the second memory cell is accessed.

A further aspect of example embodiments is directed to provide a memory cell array. The memory cell array includes a first memory cell including a first variable resistance element and a first access transistor connected to each other, one end of the first variable resistance element connected to a first bit line, a first source/drain of the first access transistor connected to a second bit line, and a gate of the first access transistor connected to a first word line; and a second memory cell including a second variable resistance element and a second access transistor connected to each other, one end of the second variable resistance element connected to the second bit line, and a gate of the second access transistor connected to a second word line.

A further aspect of example embodiments is directed to provide a memory cell array. The memory cell array includes a first memory cell including a first variable resistance element and a first access transistor connected to each other, a first source/drain of the first access transistor connected to a first bit line, a gate of the first access transistor connected to receive a first word line signal; and a second memory cell including a second variable resistance element and a second access transistor connected to each other, one end of the second variable resistance element connected to the first bit line, a gate of the second access transistor connected to receive a second word line signal. When the first access transistor is selected a read current flows from the first variable resistance element to the first bit line. When the second access transistor is selected a read current flows from the first bit line to the second variable resistance element.

### BRIEF DESCRIPTION OF THE FIGURES

Illustrative, non-limiting example embodiments will be more clearly understood from the following detailed description with reference to the following figures, wherein like reference numerals refer to like parts throughout the various figures unless otherwise specified, and wherein

FIG. 1 is an exemplary circuit diagram of a memory cell array showing a pseudo separate source line structure according to an embodiment;

FIG. 2 is an exemplary diagram schematically illustrating a memory cell array according to an embodiment;

FIG. 3 is an exemplary diagram schematically illustrating a memory cell array according to another embodiment;

FIG. 4 is an exemplary layout diagram of the memory cell array according to FIG. 3;

FIG. 5 is an exemplary diagram showing a first operation case of memory cells according to FIG. 3;

FIG. 6 is an exemplary diagram showing a second operation case of memory cells according to FIG. 3;

FIG. 7 is a block diagram schematically illustrating a nonvolatile semiconductor memory device including a memory cell array shown in FIG. 2 or 3 according to example embodiments;

FIG. 8 is a an exemplary circuit diagram of a memory cell array showing a pseudo separate source line structure according to another embodiment;

FIG. 9 is an exemplary circuit diagram schematically illustrating a memory cell array according to one embodiment;

FIG. 10 is an exemplary layout diagram of the memory cell array according to FIG. 9;

FIG. 11 is an exemplary circuit diagram showing an extended diagonal memory cell array of FIG. 8 according to an embodiment;

FIG. 12 is an exemplary circuit diagram showing an extended diagonal memory cell array of FIG. 8 according to another embodiment;

FIG. 13 is a block diagram schematically illustrating a memory system according to certain embodiments;

FIG. 14 is a block diagram schematically illustrating an exemplary nonvolatile semiconductor memory device including the memory cell array shown in FIG. 1 or 8;

FIG. 15 is a 3-dimensional diagram schematically illustrating an STT-MRAM cell as an example of a resistive memory cell applied to FIG. 14;

FIG. 16 is a block diagram schematically illustrating a portable electronic device according to certain embodiments;

FIG. 17 is a block diagram schematically illustrating an electronic system according to certain embodiments;

FIG. 18 is a diagram illustrating a semiconductor wafer according to certain embodiments;

FIG. 19 is a block diagram schematically illustrating a mobile device according to certain embodiments;

FIG. 20 is a block diagram schematically illustrating a memory card according to certain embodiments; and

FIG. 21 is a block diagram schematically illustrating a computing device according to certain embodiments.

### DETAILED DESCRIPTION

Various example embodiments will be described in detail with reference to the accompanying drawings. The present disclosure, however, may be embodied in various different forms, and should not be construed as being limited only to the illustrated embodiments. Accordingly, known processes, elements, and techniques are not described with respect to some of the embodiments. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms such as “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Example embodiments disclosed herein may include their complementary embodiments. Note that details of data access operations associated with an MRAM, internal function circuits, a common source line structure, and a separate source line structure may be skipped to prevent the disclosure from becoming ambiguous.

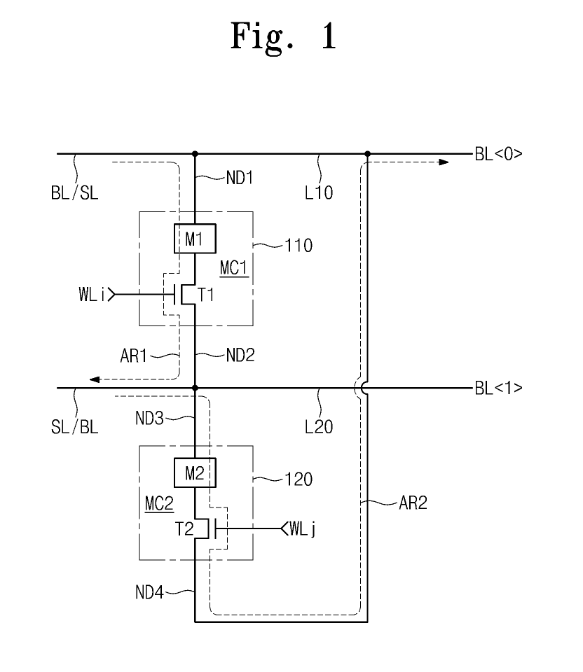

FIG. 1 is an exemplary circuit diagram of a memory cell array showing a pseudo separate source line structure according to an embodiment.

Referring to FIG. 1, a memory cell array of a nonvolatile semiconductor memory device includes a first memory cell 110 having a first node ND1 connected to a first bit line L10 and a second node ND2 connected to a second bit line L20; and a second memory cell 120 having a first node ND3 connected to the second bit line L20 and a second node ND4 connected to the first bit line L10. Each node may include, for example, a conductive terminal (e.g., a metal line) electrically connected to one or more circuit.

The first memory cell 110 includes a variable resistance element, for example, a magnetic tunnel junction (MTJ) element M1 and a selection transistor T1, and the second memory cell 120 includes an MTJ element M2 and a selection transistor T2.

For example, in one embodiment, the first and second selection transistors T1 and T2 of the first and second memory cells 110 and 120 are connected to different word lines (e.g., WLi and WLj), respectively. In one embodiment, during a read operation, when the first memory cell 110 is accessed, the second bit line L20 acts as a source line. When the second memory cell 120 is accessed, the first bit line L10 acts as a source line. Hereinafter, it is assumed that a current flows from a bit line to a source line when a corresponding memory cell is selected during a read operation of a memory device. Also, it is assumed that a line directly connected to an MTJ of a first memory cell is a bit line of the first memory cell, and a line directly connected to a selection transistor of a second memory cell is a source line of the second memory cell.

When the first memory cell 110 is accessed, a current path is formed in a direction shown by arrow AR1. In this case, the first bit line L10 acts as a bit line and the second bit line L20 acts as, for example, a pseudo source line. Thus, there is formed a pseudo separate source line structure using the second bit line L20.

When the second memory cell 120 is accessed, a current path is formed in a direction shown by arrow AR2. For example, the second bit line L20 acts as a bit line and the first bit line L10 acts as a pseudo source line. Thus, there is formed a pseudo separate source line structure using the first bit line L10.

As described above, one of two bit lines is used as a pseudo source line according to a selected memory cell.

As shown in FIG. 1, the first bit line L10 is a first bit line BL<0>, the second bit line L20 is a second bit line BL<>.

The first bit line BL<0> is used as a bit line when the first memory cell 110 is accessed, and is used as a source line when the second memory cell 120 is accessed. To show this relation, the first bit line L10 is labeled by ‘BL/SL’. An access to a memory cell means an operation where a word line connected to the memory cell is activated. An access transistor (or, a selection transistor) of a memory cell is activated to write data to a memory cell or to read data from a memory cell. In general, the access transistor is enabled by a row decoder that decodes a row address.

The second bit line BL<1> is used as a source line when the first memory cell 110 is accessed, and is used as a bit line when the second memory cell 120 is accessed. To show this relation, the second bit line L20 is labeled by ‘SL/BL’.

Each of the first and second memory cells 110 and 120 is a resistive memory cell, for example, a spin transfer torque magneto resistive random access memory (STT-MRAM) cell that includes an access transistor and an MTJ element. The access transistor means one of the first and second selection transistors T1 and T2.

In FIG. 1, each of the first and second bit lines BL<0> and BL<1> are arranged in a first direction, and the first and second memory cells 110 and 120 are disposed to be adjacent to each other in a second direction perpendicular to the first direction on the basis of the second bit line L20, for example, in a word line direction being orthogonal to a bit line direction.

Furthermore, in a different arrangement structure, the first and second memory cells 110 and 120 are disposed along a direction perpendicular to the first bit line L10 and the second bit line L20 to be in a zigzag shape. For example, in one embodiment, in the event that one end of an MTJ element M1 of the first memory cell 110 is connected to the first bit line L10, an MTJ element M2 of the second memory cell 120 disposed to be adjacent to the first memory cell 110 is connected to the second bit line L20. This connection from the first MTJ element through the second selection transistor may be referred to as a zigzag shape.

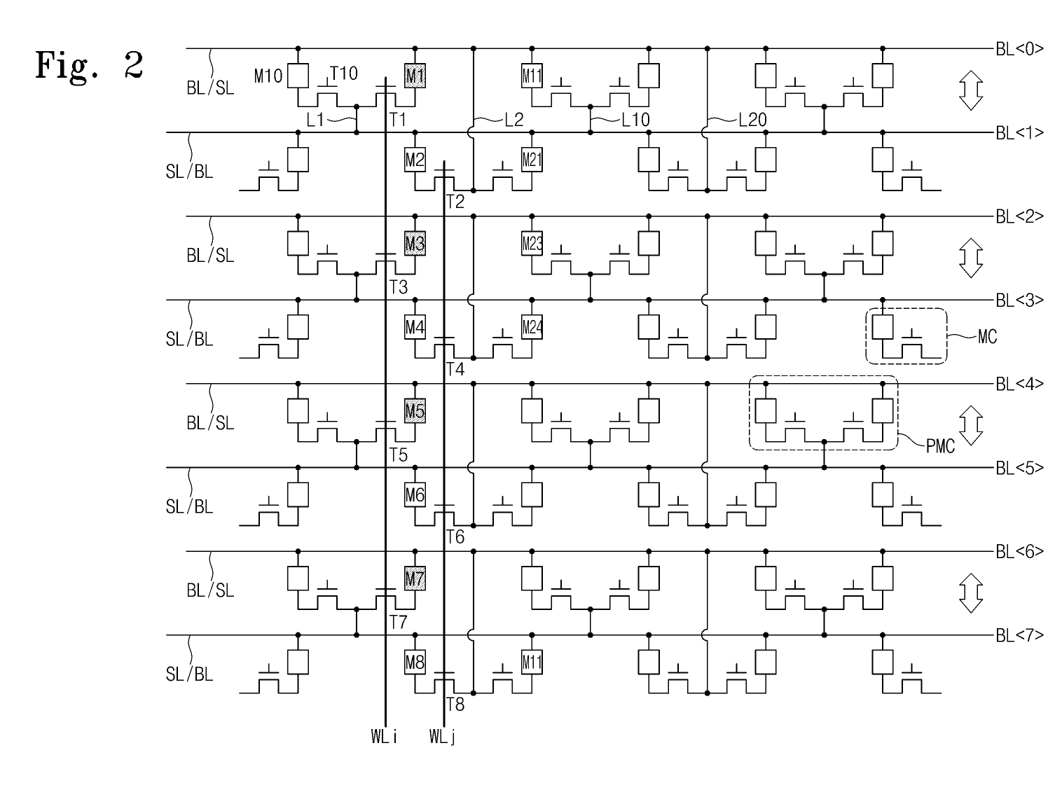

FIG. 2 is an exemplary diagram schematically illustrating a memory cell array according to an embodiment.

Referring to FIG. 2, there is illustrated a structure of a memory cell array extended on the basis of a unit arrangement shown in FIG. 1.

In FIG. 2, an MTJ element M1 and a first selection transistor T1 correspond to a first memory cell 110 shown in FIG. 1, and an MTJ element M2 and a second selection transistor T2 correspond to a second memory cell 120 shown in FIG. 1. A jump connection line L2 shown in FIG. 2 corresponds to a line that forms a current path along an arrow AR2 shown in FIG. 1, and an internal connection line L1 shown in FIG. 2 corresponds to a line that forms a current path along an arrow AR1 shown in FIG. 1.

In FIG. 2, ‘MC’ indicates a memory cell, and ‘PMC’ indicates a pair memory cell. An arrangement structure of a memory cell array shown in FIG. 2 is a structure where a plurality of pair memory cells is arranged alternately on the basis of a bit line direction to have a zigzag shape.

Referring to FIGS. 1 and 2, a first node ND1 of the first memory cell 110 is a node connected to one end of the MTJ element M1, and a second node ND2 of the first memory cell 110 is a node connected to one end of the first selection transistor T1.

Also, a first node ND3 of the second memory cell 120 is a node connected to one end of the MTJ element M2, and a second node ND4 of the second memory cell 120 is a node connected to one end of the second selection transistor T2.

In FIG. 2, a first group of memory cells may mean memory cells arranged along a bit line direction with the same connection structure as that of the first memory cell 110. For example, MTJ elements M1 and M10 form a pair memory cell and are included in the first group of memory cells. Similarly, a second group of memory cells may mean memory cells arranged along the bit line direction with the same connection structure as that of the second memory cell 120.

The first and second groups of memory cells are connected to different word lines. When the first group of memory cells is accessed, the second bit line acts as a source line. When the second group of memory cells is accessed, the first bit line acts as a source line. Thus, when the first group of memory cells is accessed, the first bit line acts as a bit line. When the second group of memory cells is accessed, the second bit line acts as a bit line.

First nodes of the first group of memory cells are nodes connected to first ends of MTJ elements, and second nodes of the first group of memory cells are nodes connected to second ends of the MTJ elements through a first group of selection transistors.

First nodes of the second group of memory cells are nodes connected to first ends of MTJ elements, and second nodes of the second group of memory cells are nodes connected to second ends of the MTJ elements through a second group of selection transistors.

When the first group of memory cells is accessed, an access to the second group of memory cells is inhibited.

As described above, a structure shown in FIG. 2 may be a modified version of a separate source line structure for driving an STT-MRAM with a low voltage. With this arrangement structure of the memory cell array, it is possible to simplify a memory cell pattern and to minimize or reduce an overhead of a chip size.

A shape of the memory cell array shown in FIG. 2 is similar to a common source line shape. However, half of adjacent bit lines are actually used as bit lines, and the others thereof are used as pseudo source lines.

A source line structure is divided into a common source line and a separate source line structure. In the common source line structure, source lines connected to all memory cells are fixed to the same level. In this case, a memory cell pattern is simple and an overhead of a chip size is small. However, it is necessary to maintain a source line level constantly (e.g., about 1V) for a bidirectional write operation. Thus, a relatively high level of write voltage may be needed. Since all source lines are connected to a power, such a structure is disadvantageous to repairing of memory cells.

In the separate source line structure, a source line is arranged for each bit line. Since a source line and a bit line are alternately switched into a high level and a low level, there is used a relatively low write voltage as compared to the common source line structure. However, since a source line is arranged for each bit line, a memory cell pattern may be complicated. In this case, an overhead of a chip size is relatively large.

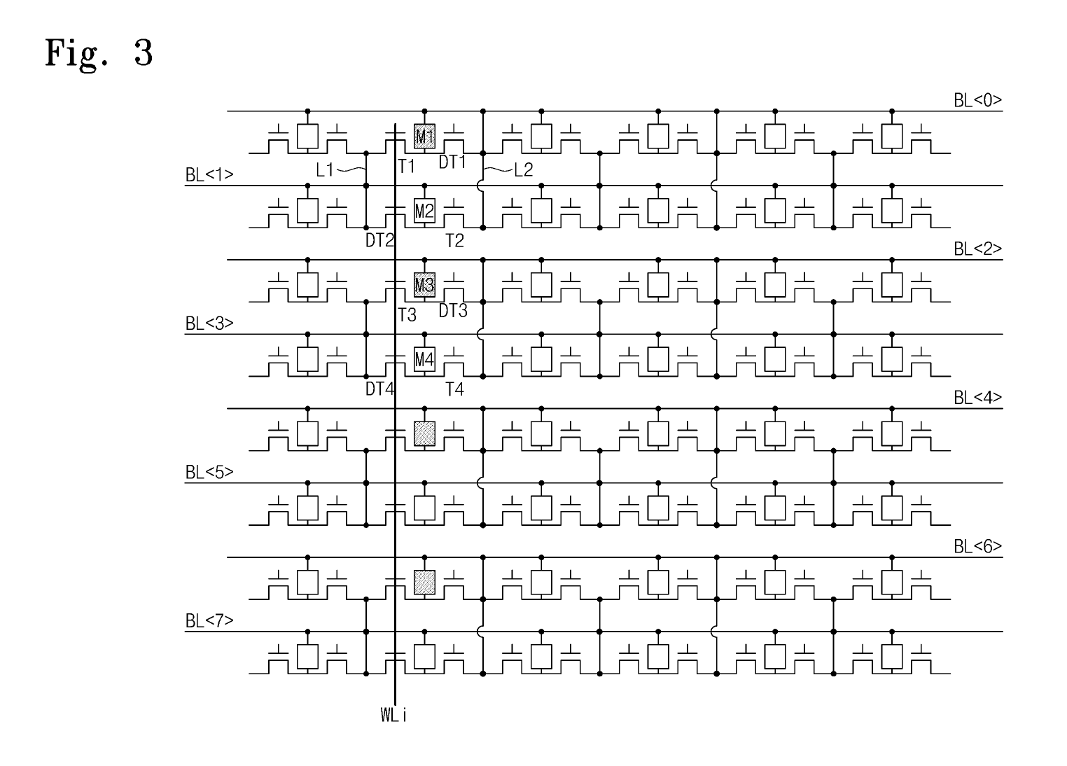

A structure shown in FIG. 2 and a structure shown in FIG. 3 are a memory cell array structure that is capable of simplifying a memory cell pattern and minimizing or reducing an overhead of a chip size.

In case of FIG. 3, as compared to FIG. 2, dummy transistors not participating in a memory access operation are further arranged for a merit of a fabricating process and isolation from an adjacent cell. In contrast, the structure shown in FIG. 2 includes access transistors actually associated with an operation of memory cells.

FIG. 3 is an exemplary diagram schematically illustrating a memory cell array according to another embodiment.

Referring to FIG. 3, a transistor that is arranged between an MTJ element M1 and a jump connection line L2 and is symmetric with a first selection transistor T1 on the basis of the MTJ element M1 is a first dummy selection transistor DT1 that does not participate in an operation of a memory cell formed of the MTJ element M1 and the first selection transistor T1. The first dummy selection transistor DT1 acts as an isolation transistor that electrically isolates adjacent memory cells. Although the first dummy selection transistor DT1 operates when a memory cell formed of an MTJ element M2 and a second selection transistor T2 operates, a voltage at one end of the MTJ element M1 is equal to the voltage at the other end. Thus, the dummy selection transistor does not affect an operation of a memory cell. This structure does not need an isolation transistor separately. L1 is a line that is connected the first selection transistor T1 and a second dummy selection transistor DT2, and L2 is a line that is connected the first dummy selection transistor DT1 and a second selection transistor T2.

Although two transistors connect to one end node of the MTJ element as illustrated in FIG. 3, only one transistor is used for an actual access operation. In another transistor, although a corresponding word line is enabled, the voltage at one end of the MTJ element M1 is equal to the voltage at the other end such that no current path is formed. Thus, the dummy selection transistor is used for electrical isolation from an immediately adjacent memory cell with a corresponding word line being disabled.

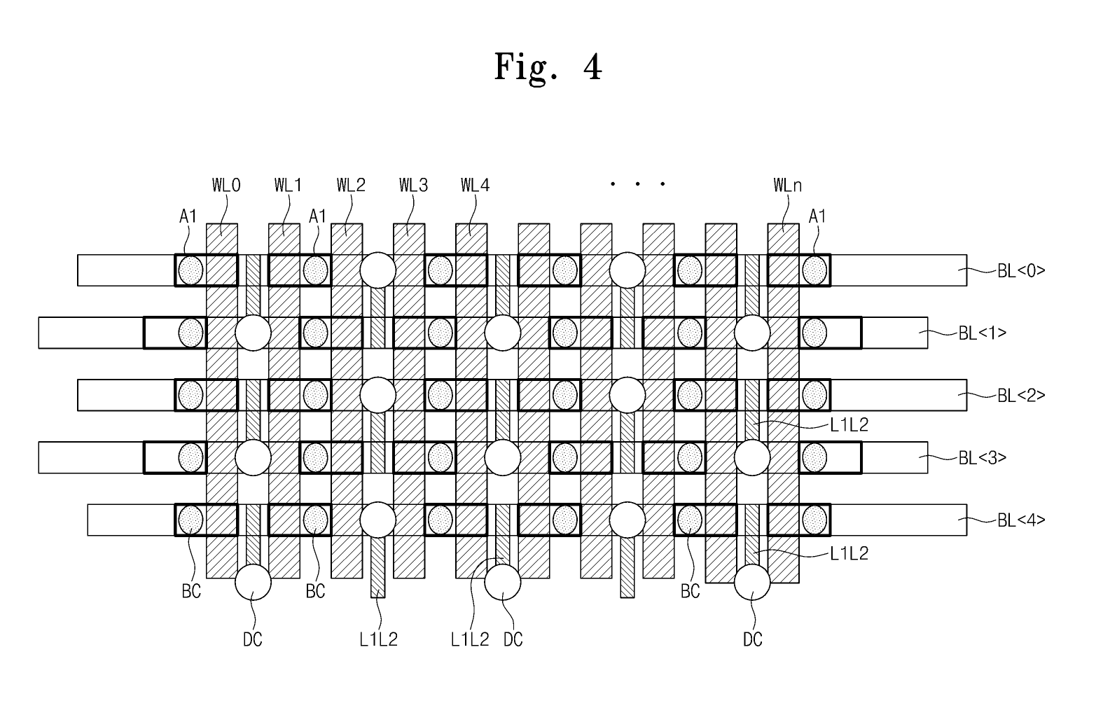

FIG. 4 is an exemplary layout diagram of the memory cell array according to FIG. 3.

Referring to FIGS. 3 and 4, a reference symbol ‘A1’ indicates a memory cell including an MTJ element. Bit lines are arranged in a first direction, and word lines are arranged in a second direction being orthogonal to the first direction. ‘L1L2’ indicates a jump connection lines L1 and L2 forming lines that connect the first selection transistor T1 to a second dummy selection transistor DT2, and the first dummy selection transistor DT1 to a second selection transistor T2, respectively. ‘BC’ and ‘DC’ indicate a buried contact and a direct contact, respectively.

In FIGS. 3 and 4, by connection lines L1 and L2, when one of two bit lines adjacent to each other operates, the other bit line acts as a pseudo source line. The jump connection line L2 disposed in a word line direction is separated by a unit of two bit lines. ‘BC’ is a contact for connecting an MTJ element and a common source/drain of a selection transistor and a dummy selection transistor. ‘DC’ is a contact for connecting a bit line and a common source/drain of two dummy selection transistors disposed adjacent to each other.

Referring to FIG. 4, a first set of memory cells are arranged along the first bit line and a second set of memory cells are arranged along the second bit line to be adjacent to each other in a zigzag shape along the first direction. The first and second bit lines are spaced apart in the second direction and the first and second set of memory cells are arranged diagonally with respect to each other and the first and second directions.

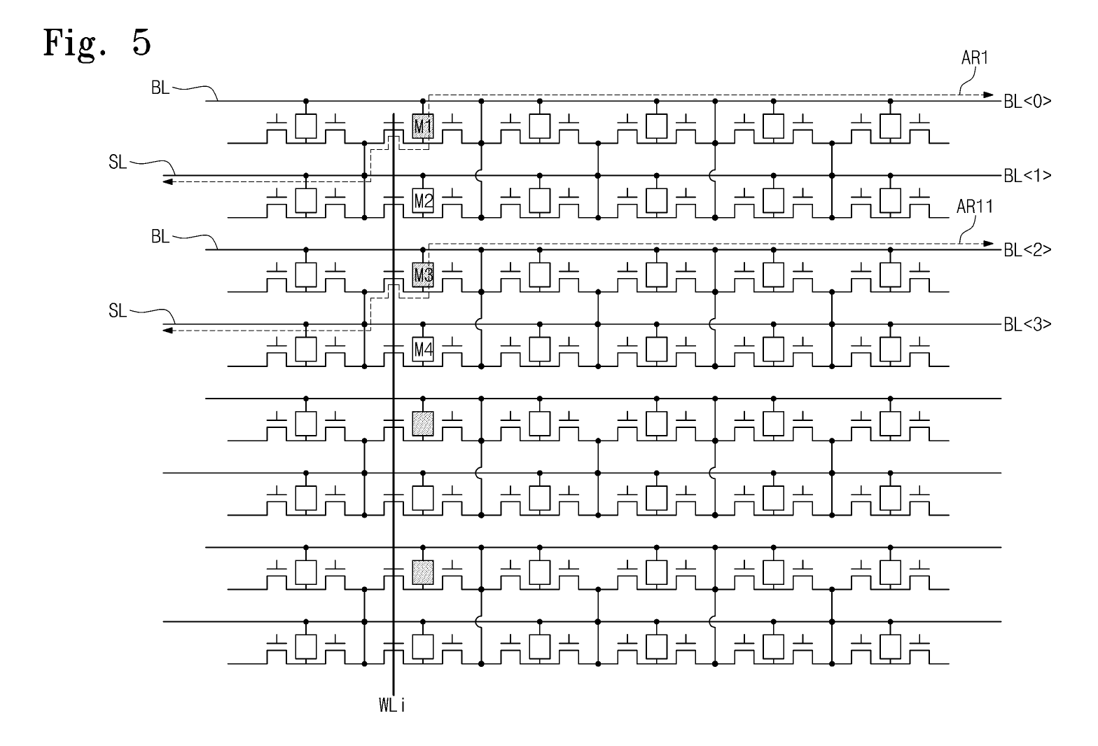

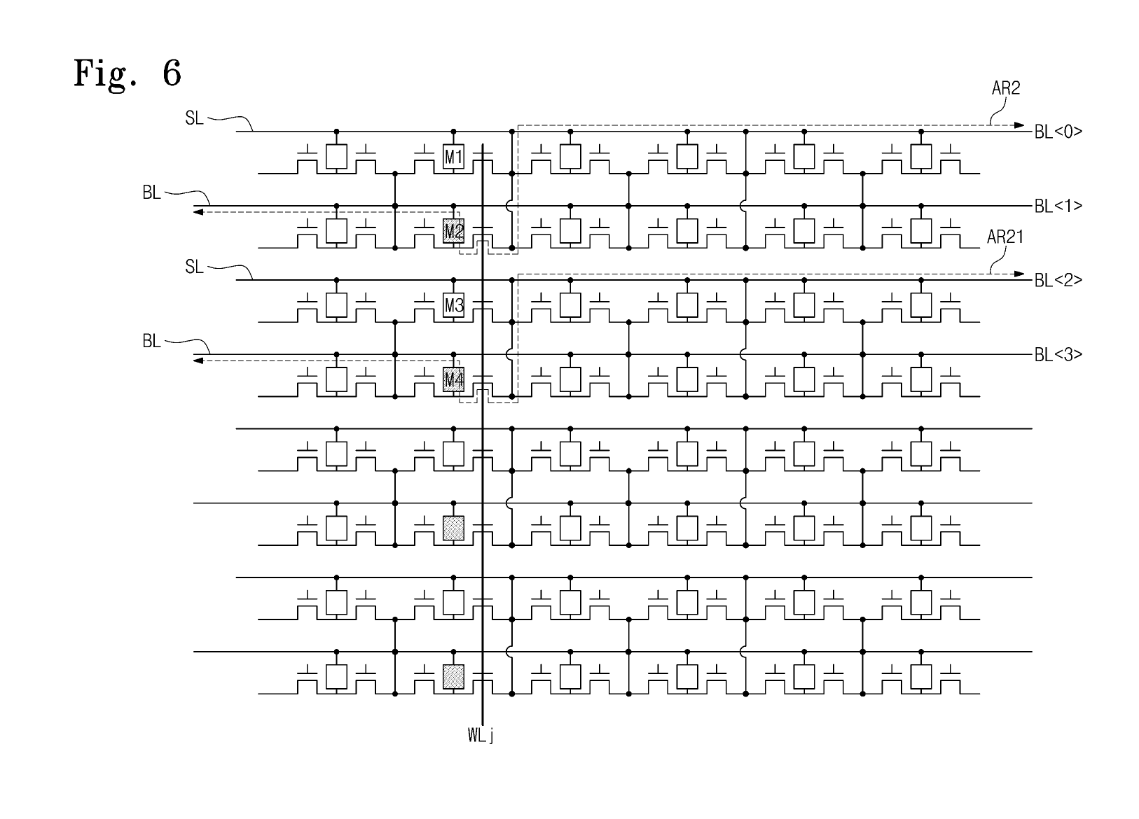

FIG. 5 is an exemplary diagram showing a first operation case of memory cells according to FIG. 3. FIG. 6 is an exemplary diagram showing a second operation case of memory cells according to FIG. 3.

For ease of description, in FIG. 5, bit lines BL<0> and BL<2> are referred to as even bit lines and bit lines BL<1> and BL<3> are referred to as odd bit lines. A first operation case shown in FIG. 5 is such a case that memory cells connected to even bit lines are accessed by an enabling signal applied to a word line WLi. For example, current paths are formed along arrows AR1 and AR11, so that even bit lines are used as bit lines and odd bit lines are used as source lines. Though not shown, a voltage source or a current source may be connected between a respective even bit line and a corresponding odd bit line. When the selected word line WLi is enabled, MTJ elements connected to the even bit lines are accessed and voltages across MTJ elements connected to the odd bit lines are equal although odd selection transistors corresponding thereto are turned on. Therefore, the odd selection transistors turned on by an enabling of the word line WLi don't participate in an actual memory cell access operation.

A second operation case shown in FIG. 6 is opposite to the first operation case described with reference to FIG. 5.

The second operation case shown in FIG. 6 is such a case that memory cells connected to odd bit lines are accessed by a signal applied to a word line WLj. For example, current paths are formed along arrows AR2 and AR21, so that odd bit lines are used as bit lines and even bit lines are used as source lines. When the selected word line WLj is enabled, MTJ elements connected to the odd bit lines are accessed and voltages across MTJ elements connected to the even bit lines are equal although even selection transistors corresponding thereto are turned on. Therefore, the even selection transistors turned on by an enabling of the word line WLj don't participate in an actual memory cell access operation.

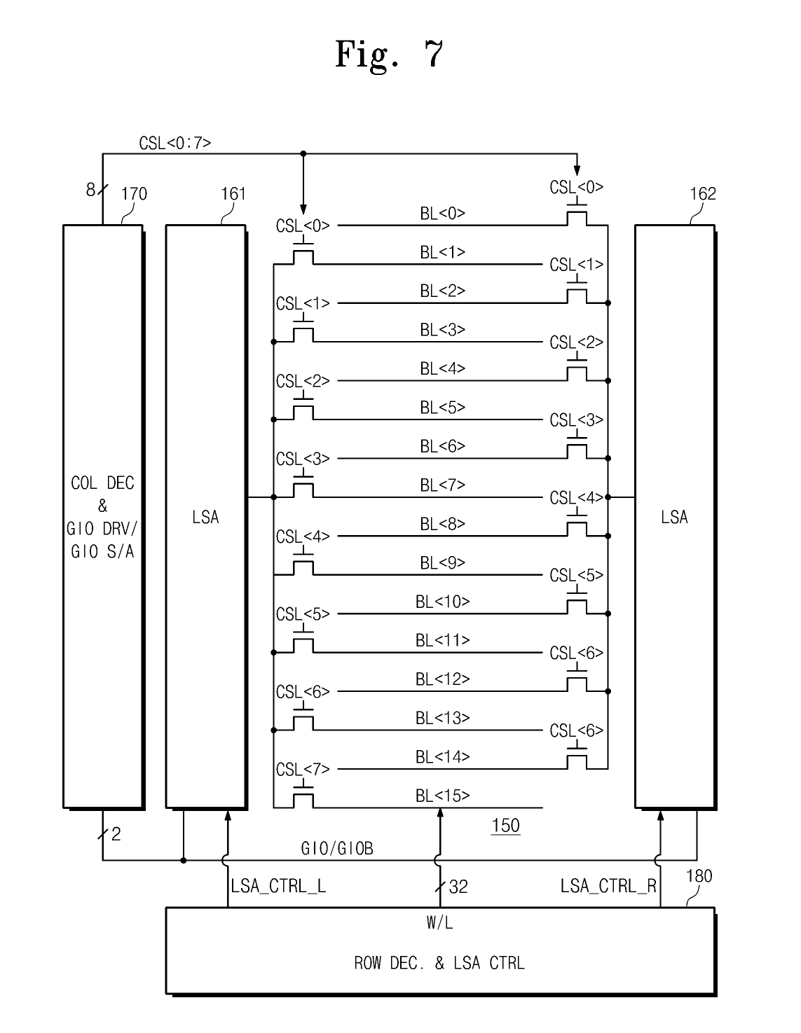

FIG. 7 is a block diagram schematically illustrating a nonvolatile semiconductor memory device including a memory cell array shown in FIG. 2 or 3 according to example embodiments.

Referring to FIG. 7, there are illustrated a memory cell array 150, a first local sense amplifier circuit 161, a second local sense amplifier circuit 162, a row decoder and local sense amplifier control circuit 180, and a column decoder and global input/output driver/sense amplifier circuit 170.

The first local sense amplifier circuit 161 and the second local sense amplifier circuit 162 may act as a general bit line sense amplifier. The first local sense amplifier circuit 161 and the second local sense amplifier circuit 162 may be a current type sense amplifier formed using differential amplifiers.

In FIG. 7, there is shown such a structure that two bit lines adjacent to each other are controlled by the same column selection line (CSL) signal applied to column selection transistors connected to first and second bit lines BL<0> and BL<1>. A column decoder of the column decoder and global input/output driver/sense amplifier circuit 170 may generate column selection signals CSL<0:7> to select at least one pair of bit lines.

During a data read operation, one of the first local sense amplifier circuit 161 and the second local sense amplifier circuit 162 disposed at both sides of the memory cell array 150 performs an operation of sensing data. The other of the first local sense amplifier circuit 161 and the second local sense amplifier circuit 162 connects a source power Vsource (e.g., 0V) to an unselected bit line (e.g., a source line). Data sensed by a local sense amplifier circuit participating in an actual operation is applied to a GIO sense amplifier of the column decoder and global input/output driver/sense amplifier circuit 170 through GIO/GIOB lines. Data output through the GIO sense amplifier may read out to an external device.

For example, write data provided from the external device during a write operation is transferred to the memory cell array 150 of a memory device through a GIO driver and the GIO/GIOB lines.

One of the first local sense amplifier circuit 161 and the second local sense amplifier circuit 162 disposed at both sides of the memory cell array 150 applies a high voltage Vwrite for writing to a corresponding bit line, and the other thereof applies a low voltage Vsource for writing to a corresponding bit line (e.g., a corresponding pseudo source line).

The block diagram of a memory device shown in FIG. 7 is only exemplary. Another scheme may be utilized without limitation.

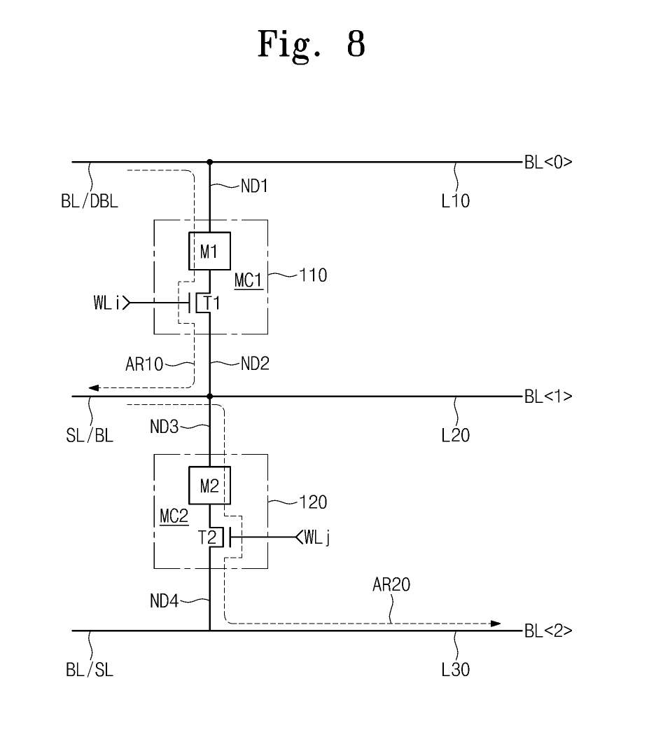

FIG. 8 is an exemplary circuit diagram of a memory cell array showing a pseudo separate source line structure according to another embodiment.

Referring to FIG. 8, a memory cell array of a nonvolatile semiconductor memory device includes a first memory cell 110 having a first node ND1 connected to a first bit line L10 and a second node ND2 connected to a second bit line L20; and a second memory cell 120 having a first node ND3 connected to the second bit line L20 and a second node ND4 connected to a third bit line L30.

The first memory cell 110 includes a variable resistance element, for example, a magnetic tunnel junction (MTJ) element M1 and a selection transistor T1, and the second memory cell 120 includes an MTJ element M2 and a selection transistor T2.

For example, the first and second selection transistors T1 and T2 of the first and second memory cells 110 and 120 are connected to different word lines WLi and WLj, respectively.

During a read operation when the second memory cell 120 is accessed, a current path is formed along an arrow AR20 shown in FIG. 8. At this time, the third bit line L30 is used as a source line SL. When the first memory cell 110 is accessed, a current path is formed along an arrow AR10 shown in FIG. 8. At this time, the second bit line L20 is used as a source line SL.

When the first memory cell 110 is accessed, the first bit line L10 acts as a bit line. When the second memory cell 120 is accessed, the second bit line L20 acts as a bit line.

In a structure shown in FIG. 8, when the first memory cell 110 is accessed, a last bit line BL<n> of a memory cell array is used as a dummy bit line DBL that does not participate in an access operation of the memory cell array.

Also, when the second memory cell 120 is accessed, the first bit line L10 is used as a dummy bit line DBL that does not participate in an access operation of the memory cell array.

Similarly to FIG. 1, in FIG. 8, a first node of the first memory cell 110 is a node connected to one end of the MTJ element M1, and a second node ND2 of the first memory cell 110 is a node connected to one end of the first selection transistor T1. A first node of the second memory cell 120 is a node connected to one end of the MTJ element M2, and a second node of the second memory cell 120 is a node connected to one end of the second selection transistor T2.

In FIG. 8, there is illustrated such a structure that the first memory cell 110 and the second memory cell 120 are arranged to be adjacent to each other in a second direction (a word line direction perpendicular to a bit line) on the basis of a second bit line L20.

With a memory cell array structure shown in FIG. 8, an upper bit line of a memory cell actually accessed is used as a bit line, and a lower bit line thereof is used as a source line. Also, one of the uppermost bit line and the lowermost bit line is set to a dummy bit line according to whether an enabled word line is disposed at a left side or at a right side on the basis of an MTJ element.

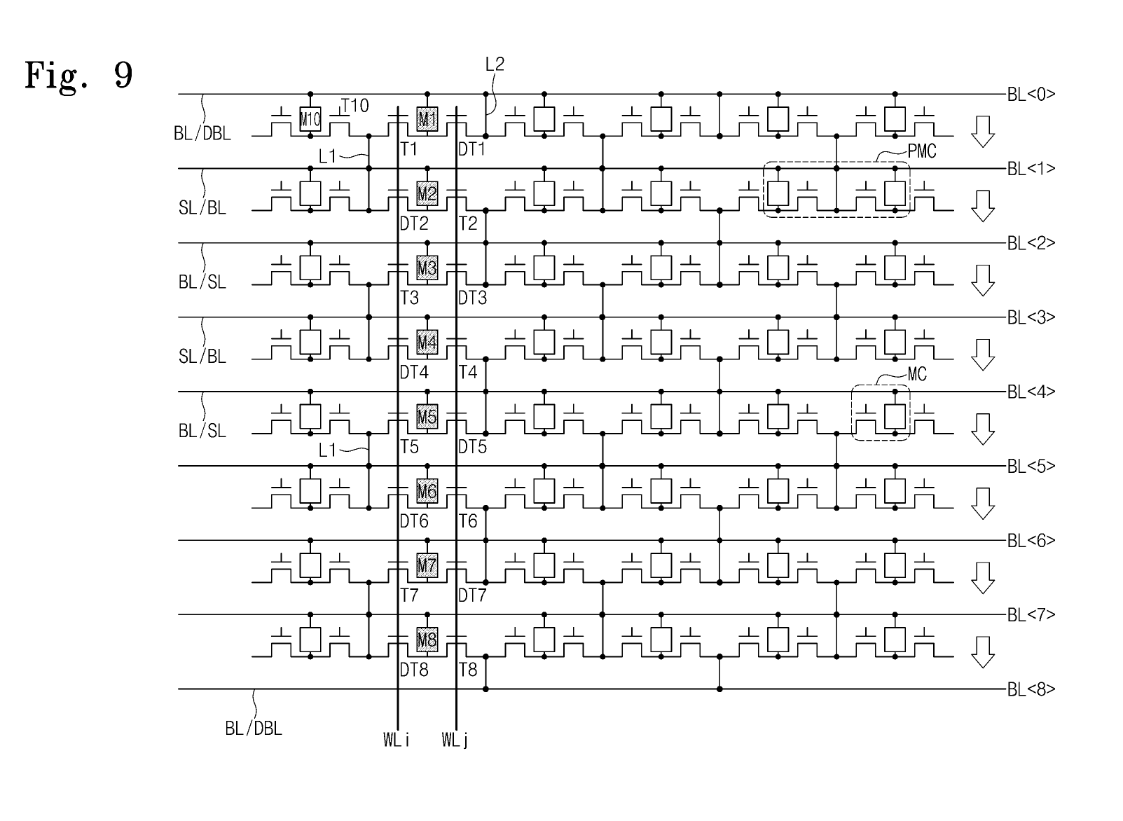

In FIG. 9, when odd bit lines BL<1>, BL<3>, and BL<5> are selected, the uppermost bit line BL<0> is a dummy bit line that does not participate in an actual memory cell operation. Of source, in the event that a memory cell including the MTJ element M1 is selected, the uppermost bit line BL<0> is used as a bit line.

FIG. 9 is an exemplary circuit diagram schematically illustrating a memory cell array according to one embodiment.

Referring to FIG. 9, there is illustrated a structure of a memory cell array extended on the basis of a unit arrangement shown in FIG. 8.

In FIG. 9, an MTJ element M1 and a first selection transistor T1 correspond to a first memory cell 110 shown in FIG. 8, and an MTJ element M2 and a second selection transistor T2 correspond to a second memory cell 120 shown in FIG. 8.

In one embodiment, during a read operation a current path following an arrow AR10 shown in FIG. 8 is implemented by a path that sequentially passes through BL<0>, M1, T1, and BL<1> when a left word line WLi is enabled. For example, the bit line BL<0> is used as a bit line and the bit line BL<1> is used as a source line.

In one embodiment, during a read operation a current path following an arrow AR20 shown in FIG. 8 is implemented by a path that sequentially passes through BL<1>, M2, T2, and BL<2> when a right word line WLj is enabled. For example, the bit line BL<1> is used as a bit line, the bit line BL<2> is used as a source line and the bit line BL<0> is used as a dummy bit line.

In FIG. 9, ‘MC’ indicates a memory cell, and ‘PMC’ indicates a pair memory cell.

An arrangement structure of a memory cell array shown in FIG. 9 is a structure where a plurality of pair memory cells is arranged in a bilateral symmetry shape.

Referring to FIGS. 8 and 9, a first node ND1 of the first memory cell 110 is a node connected to one end of the MTJ element M1, and a second node ND2 of the first memory cell 110 is a node connected to one end of the first selection transistor T1.

Also, a first node ND3 of the second memory cell 120 is a node connected to one end of the MTJ element M2, and a second node ND4 of the second memory cell 120 is a node connected to one end of the second selection transistor T2.

Referring to FIG. 9, L1 is a line that connects the first selection transistor T1 to a second dummy selection transistor DT2, and L2 is a line that connects the second selection transistor T2 to a third dummy selection transistor DT3.

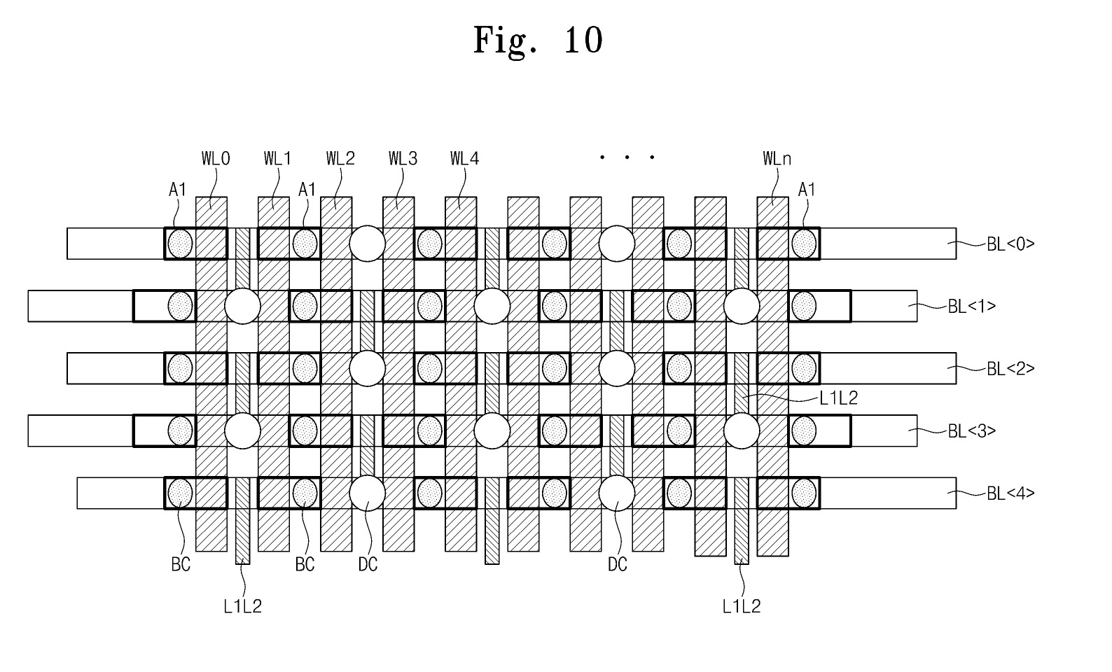

FIG. 10 is an exemplary layout diagram of the memory cell array according to FIG. 9.

Referring to FIGS. 9 and 10, a reference symbol ‘A1’ indicates a memory cell including an MTJ element. Bit lines are arranged in a first direction, and word lines are arranged in a second direction being orthogonal to the first direction. ‘L1L2’ indicates a jump connection lines L1 and L2 forming lines that are connected the first selection transistor T1 with a second dummy selection transistor DT2, and the second selection transistor T2 with a third dummy selection transistor DT3, respectively. ‘BC’ and ‘DC’ indicate a buried contact and a direct contact, respectively.

In FIGS. 9 and 10, by connection lines L1 and L2, bit lines placed at the top of selected memory cells are used as bit lines and bit lines placed at the bottom of the selected memory cells are used as source lines (e.g., pseudo source lines). The connection line L1 disposed in a word line direction is separated by a unit of two bit lines. ‘BC’ is a contact for connecting an MTJ element and a common source/drain of a selection transistor and a dummy selection transistor. ‘DC’ is a contact for connecting a bit line and a common source/drain of two dummy selection transistors disposed adjacent to each other.

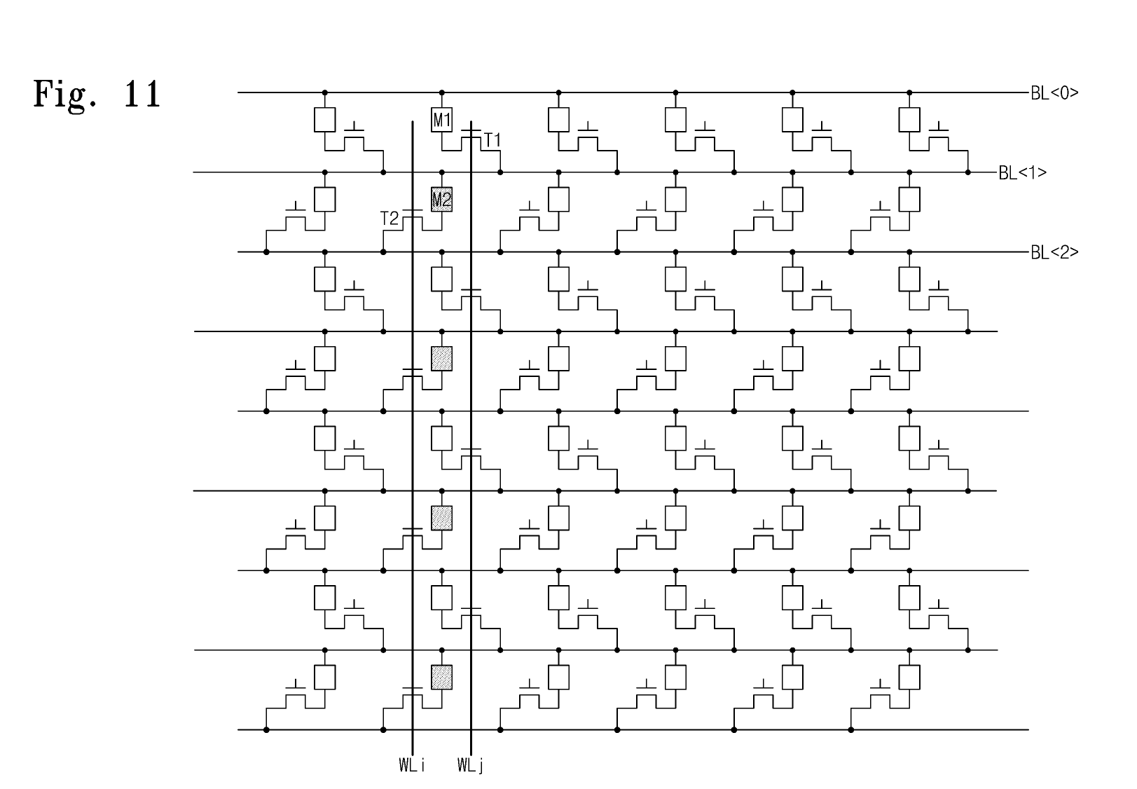

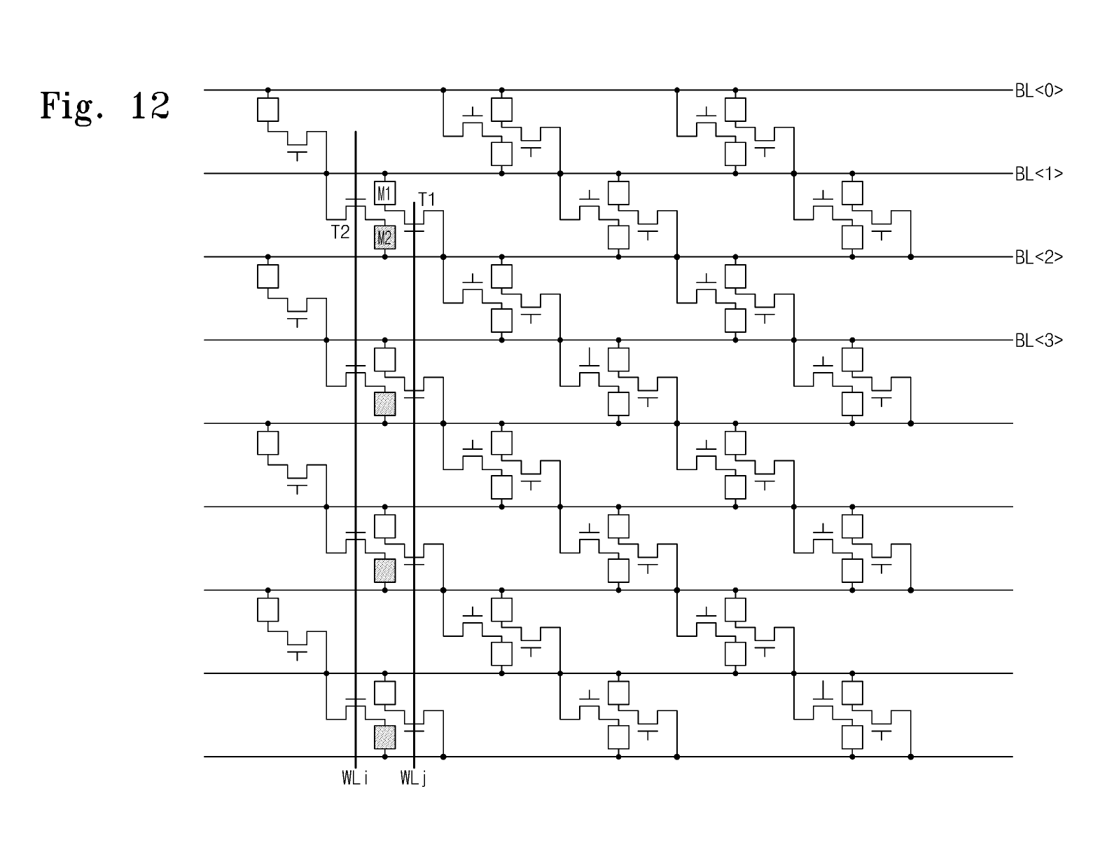

FIG. 11 is an exemplary circuit diagram showing an extended diagonal memory cell array of FIG. 8 according to an embodiment. FIG. 12 is an exemplary circuit diagram showing an extended diagonal memory cell array of FIG. 8 according to another embodiment.

In case of FIG. 11, an N+ active area of a selection transistor of a memory cell accessing an MTJ element is disposed in a zigzag shape. Like FIG. 9, one of two bit lines adjacent to each other is used as a bit line and the other thereof is used as a source line. When a left word line WLi of a memory cell is enabled, the uppermost bit line BL<0> is a dummy bit line not participating in an operation, and a second bit line BL<1>, a fourth bit line BL<3>, a sixth bit line and an eighth bit line placed at the bottom of the uppermost bit line BL<0> act as actual bit lines. Meanwhile, a third bit line BL<2>, a fifth bit line, a seventh bit line, and a ninth bit line are used as pseudo source lines.

When a right word line WLj of a memory cell is enabled, bit line and source line roles are changed.

Referring to FIG. 11, two contacts may be connected to the N+ active area. For example, one may be a contact for connecting an MTJ element and an N+ active area, and the other may be a contact for connecting a bit line and the N+ active area.

In case of FIG. 12 which shows a pseudo separate source line structure having a diagonal arrangement shape, N+ active areas of selection transistors are disposed in the same direction.

When the left word line WLi of a memory cell is enabled, the uppermost bit line BL<0> is a dummy bit line not participating in an operation, and a second bit line BL<1>, a fourth bit line BL<3>, a sixth bit line and an eighth bit line placed at the bottom of the uppermost bit line BL<0> act as source lines. Meanwhile, a third bit line BL<2>, a fifth bit line, a seventh bit line, and a ninth bit line are used as actual bit lines. When the right word line WLj of a memory cell is enabled, bit line and source line roles are changed.

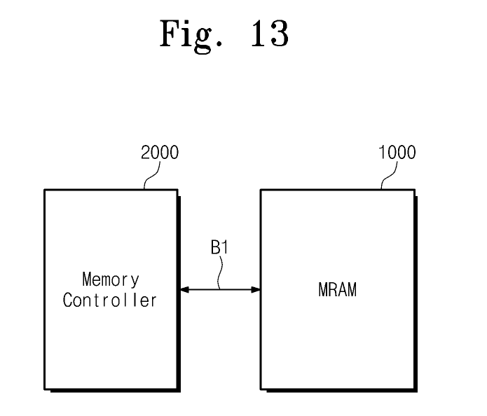

FIG. 13 is a block diagram schematically illustrating a memory system according to certain embodiments.

Referring to FIG. 13, a memory system includes a memory controller 2000 and a magnetic RAM (MRAM) 1000.

The MRAM 1000 has a memory cell array structure such as shown, for example, in FIG. 1 or 8.

The memory controller 2000 is connected to a host (not shown). The memory controller 200 accesses the MRAM 1000 in response to a request from the host.

The memory controller 2000 transfers an address, data and control signals to the MRAM 1000 through a bus B1.

In exemplary embodiments, the memory controller 2000 may further comprise components such as a processing unit, a host interface, a memory interface, etc.

The processing unit controls an overall operation of the memory controller 2000.

The host interface may include a variety of protocols for data exchange between the memory controller 2000 and the host. The memory controller 2000 is configured to communicate with the host or an external device using at least one of various protocols such as USB (Universal Serial Bus) protocol, MMC (multimedia card) protocol, PCI (peripheral component interconnection) protocol, PCI-E (PCI-express) protocol, ATA (Advanced Technology Attachment) protocol, Serial-ATA protocol,

Parallel-ATA protocol, SCSI (small computer small interface) protocol, ESDI (enhanced small disk interface) protocol, and IDE (Integrated Drive Electronics) protocol.

The memory system shown in FIG. 13 may be provided as one of various components of an electronic device such as a computer, a ultra-mobile personal computer (UMPC), a workstation, a net-book, a personal digital assistance (PDA), a portable computer (PC), a web tablet, a wireless phone, a mobile phone, a smart phone, a smart television, a three-dimensional television, an e-book, a portable multimedia player (PMP), a portable game console, a navigation device, a black box, a digital camera, a digital multimedia broadcasting (DMB) player, a digital audio recorder, a digital audio player, a digital picture recorder, a digital picture player, a digital video recorder, a digital video player, a device for transmitting and receiving information in a wireless environment, one of various electronic devices constituting a home network, one of various electronic devices constituting a computer network, one of various electronic devices constituting a telematics network, a radio frequency identification (RFID) device, and one of various components constituting a computing system.

With the memory system shown in FIG. 13, since an overhead of a chip size of the MRAM 1000 is minimized or reduced, a cost of the memory system is reduced.

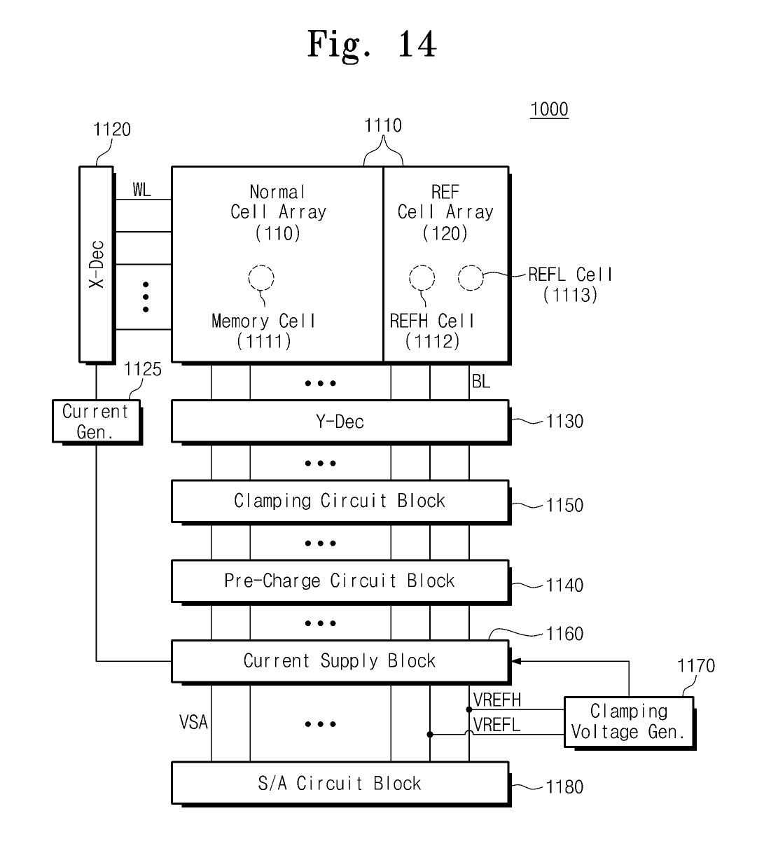

FIG. 14 is a block diagram schematically illustrating an exemplary nonvolatile semiconductor memory device including the memory cell array shown in FIG. 1 or 8.

A nonvolatile semiconductor memory device 1000 includes a memory cell array 1110, a row decoder 1120 for selecting a word line WL of the memory cell array 1110, a column decoder 1130 for selecting a bit line BL of the memory cell array 1110, a pre-charge circuit block 1140 for performing a pre-charge operation on a bit line BL, a clamping circuit block 1150 for clamping a voltage of the bit line BL, a current generating unit 1125 for generating a current to be supplied to a memory cell read circuit, a current supply block 1160 for constantly providing a current generated by the current generating unit 1125 to the bit line BL, a sense amplifier circuit block 1180 for sensing and amplifying a current difference of the bit line BL, and a clamping voltage generating unit 1170 for adjusting a clamping voltage VCMP according to a variation in a cell resistance value of the memory cell array 1110.

The memory cell read circuit may include various circuit components for reading data stored in a memory cell. For example, a current generated by the current generating unit 1125 is provided to a word line or a bit line for a read operation of a memory cell.

The memory cell array 1110 includes a normal memory cell array 110 and a reference cell array 120. The normal memory cell array 110 includes memory cells 1111 formed at intersections of word lines and bit lines. In certain embodiments, the normal memory cell array 110 has an arrangement structure described with reference to FIGS. 2, 3, 9, 11, and 12.

The reference cell array 120 includes reference cells 1112 and 1113 as first and second reference resistors RMTJH and RMTJL.

For example, the reference cells 1112 and 1113 may be configured substantially the same as the normal memory cell 1111 storing data. Data corresponding to a logically high level (e.g., data 1) or a logically low level (e.g., data ‘0’) is stored in the reference cells 1112 and 1113. For example, logically low data is written at some cells (e.g., the first reference cell 1113) of the reference cell array 120, and logically high data is written at other cells (e.g., the second reference cell 1112) thereof.

A write operation on the reference cells 1112 and 1113 is performed together with a write operation on the memory cell 1111. A write operation on the reference cells 1112 and 1113 is performed once, and the first and second reference resistors RMTJH and RMTJL are obtained by iteratively reading the reference cells 1112 and 1113 thus written. In the event that the memory cell 1111 is implemented by an MRAM cell, a value of data stored in the memory cell 1111 or the reference cells 1112 and 1113 is changed by lapse of time. For this reason, a data rewriting operation on the memory cell 1111 is performed periodically. For example, a rewriting operation on the reference cells 1112 and 1113 is performed at the rewriting operation on the memory cell 1111.

The reference cells 1112 and 1113 are disposed to correspond to at least a part of word lines or to correspond to all word lines. When a word line is selected for a data reading or writing operation, data is written at the reference cells 1112 and 1113 connected to the selected word line, or data is read from the reference cells 1112 and 1113 connected to the selected word line to generate a reference current by the first and second reference resistors RMTJH and RMTJL.

In operation, each of the row decoder 1120 and the column decoder 1130 includes MOS transistor based switches. The row decoder 1120 selects word lines WL in response to a row address, and the column decoder 1130 selects bit lines BL in response to a column address. The pre-charge circuit block 1140 pre-charges the bit lines BL with a pre-charge voltage. The clamping circuit block 1150 clamps voltages of the bit lines BL in response to a clamping voltage VCMP from the clamping voltage generating unit 1170. A current generated from the current generating unit 1125 is provided to each read path through the current supply block 1160.

During a data reading operation, voltage levels of the bit lines BL pre-charged are varied according to data values of the memory cells 1111. For example, during the data reading operation, a bit line voltage may be developed according to a data value stored in a memory cell.

The memory cell 1111 has a relatively large resistance value or a relatively small resistance value according to data written at the memory cell 1111. The amount of current supplied to the sense amplifier circuit block 1180 is variable according to the resistance value of the memory cell 1111. The sense amplifier circuit block 1180 includes a plurality of sense amplifier circuits. A current difference developed by data stored in the memory cell 1111 is sensed and amplified, and is output as a voltage difference.

Bit lines are additionally disposed to correspond to the reference cell array 120, and a pre-charge operation and a selection operation on a reference cell read path are performed substantially the same or similar to those of a normal memory cell read path. During a data reading operation, the column decoder 1130 selects bit lines connected to the first reference cell 1112 and the second reference cell 1113. Currents of bit lines connected to the first reference cell 1112 and the second reference cell 1113 are developed.

The clamping voltage generating unit 1170 detects variations in first and second reference voltages VREFL and VREFH due to variations in first and second reference currents and adjusts a level of the clamping voltage VCMP. The clamping circuit block 1150 controls a level of a clamping voltage applied to a bit line, based on the clamping voltage VCMP thus adjusted. The sense amplifier circuit block 1180 outputs data by performing an operation of a current sense amplifier shown in FIG. 2 or 3.

Embodiments of the inventive concepts are described mainly using an MRAM. However, the nonvolatile memory device may be formed of a phase change RAM (PRAM) or a resistive memory device such as a resistive RAM (RRAM) using a variable resistance material, a ferroelectric RAM (FRAM) using a ferroelectric capacitor, etc.

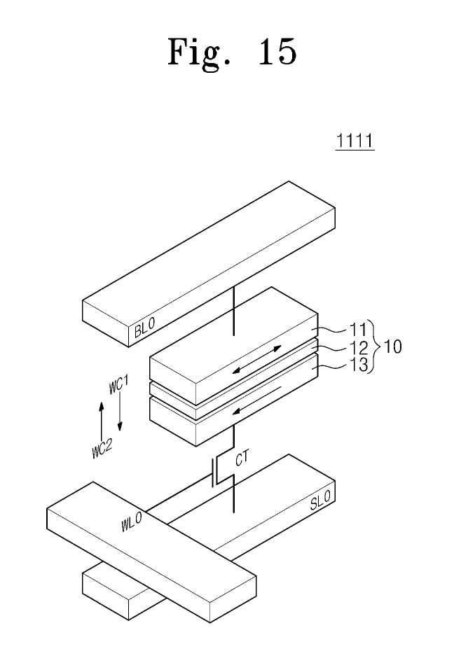

FIG. 15 is a 3-dimensional diagram schematically illustrating an STT-MRAM cell as an example of a resistive memory cell applied to FIG. 14.

Referring to FIG. 15 that shows an example of an STT-MRAM (Spin Transfer Torque Magneto Resistive Random Access Memory) cell, a memory cell 1111 includes an MTJ (Magnetic Tunnel Junction) element 10 and a selection transistor CT. A gate of the selection transistor CT is connected to a word line (e.g., a first word line WL0), and one electrode thereof is connected to a bit line (e.g., a first bit line BL0) through the MTJ element 10. Also, the other electrode of the selection transistor CT is connected to a source line (e.g., a first source line SL0).

In exemplary embodiments, source lines are implemented by bit lines without separate formation.

The MTJ element 10 includes a fixed layer 13, a free layer 11, and a tunnel layer 12 formed between the free layer 11 and the tunnel layer 12. A magnetization direction of the fixed layer 13 is fixed, and a magnetization direction of the free layer 11 is equal or opposite to that of the fixed layer 13 according to a condition. An anti-ferromagnetic layer (not shown) may be further provided to fix a magnetization direction of the fixed layer 13.

The free layer 11 includes a material having a variable magnetization direction. A magnetization direction of the free layer 11 is changed by electrical/magnetic factors provided from the inside or outside of a memory cell. The free layer 11 includes a ferromagnetic material having at least one of cobalt (Co), iron (Fe), and nickel (Ni). For example, a material of the free layer 11 may be one selected from a group of FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12.

A thickness of the barrier layer 12 is less than a spin diffusion distance. The barrier layer 11 includes a non-magnetic material. For example, the barrier layer 11 includes at least one selected from a group of magnesium (Mg) oxide, titanium (Ti) oxide, aluminum (Al) oxide, magnesium-zinc (MgZn) oxide, magnesium-boron (MgB) oxide, titanium (Ti) nitride, and vanadium (V) nitride.

The pinned layer being the fixed layer 13 has a magnetization direction fixed by the anti-ferromagnetic layer. Also, the pinned layer includes a ferromagnetic material. For example, the pinned layer includes at least one selected from a group of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12.

The pinning layer includes an anti-ferromagnetic material. For example, the pinning layer includes at least one selected from a group of PtMn, IrMn, MnO, MnS, MnTe, MnF2, FeCl2, FeO, CoCl2, CoO, NiCl2, NiO, and Cr.

A resistance value of the MTJ element 10 is variable according to a magnetization direction of the free layer 11. At this time, when a magnetization direction of the pinned layer 13 is parallel with that of the free layer 11, the MTJ element 10 has a low resistance value and stores data ‘0’. Also, when a magnetization direction of the pinned layer 13 is anti-parallel with that of the free layer 11, the MTJ element 10 has a high resistance value and stores data ‘1’. In FIG. 15, there is illustrated an embodiment where the free layer 11 and the pinned layer 13 of the MTJ element 10 are formed of a horizontal magnetic element. However, the inventive concepts are not limited thereto. For example, the free layer 11 and the pinned layer 13 of the MTJ element 10 may be formed of a vertical magnetic element.

To perform a write operation of the STT-MRAM, a high-level voltage is applied to the word line WL0 to turn the selection transistor CT on. A write current WC1 or WC2 is applied between the bit line BL0 and the source line SL0. A magnetization direction of the free layer 11 is decided according to a direction of the write current WC1 or WC2. For example, when a first write current WC1 is applied, free electrons having the same spin direction as that of the fixed layer 13 force a torque to the free layer 11, so that the free layer 11 is magnetized in the same direction as that of the fixed layer 13. When a second write current WC2 is applied, electrons having a spin direction opposite to that of the fixed layer 13 return to the free layer 11 to force a torque. At this time, the free layer 11 is magnetized in a direction opposite to that of the fixed layer 13. In the MTJ element 10, a magnetization direction of the free layer 11 is changed by a spin transfer torque (STT).

To perform a read operation of the STT-MRAM, a high-level voltage is applied to the word line WL0 to turn on the selection transistor CT, and a read current is applied in a direction from the bit line BL0 to the source line SL0. Under this bias condition, data stored in the MTJ element 10 is determined. At this time, since a level of the read current is lower than that of the write current WC1 or WC2, a magnetization direction of the free layer 11 is not changed by the read current.

In case of the STT-MRAM where data is written by the spin transfer torque, a difference between a reference voltage for determining data and a data voltage is about 100mV to 200mV. A resistance value of the MTJ element is continuously changed by various causes. In the event that a level of a data voltage is varied according to a variation in a resistance value of a memory cell, the reliability on a data read operation is lowered.

In case of FIG. 14, reference cells are implemented by writing data 1 or data 0 at a normal memory cell configured as illustrated in FIG. 15 without separate fabrication of reference cells. Thus, it is unnecessary to fabricate a reference cell separately.

With a structure shown in FIG. 14 using a memory cell shown in FIG. 12, a pair of first and second reference cells 1112 and 1113 is disposed to correspond to a plurality of memory cells of a memory cell array 1110. Thus, burden on area penalty is reduced. For example, a plurality of memory cells and the first and second reference cells 1112 and 1113 are disposed to correspond to a word line, and a plurality of sense amplifier circuits for sensing data of the memory cells may utilize first and second reference resistance values of the first and second reference cells 1112 and 1113 in common.

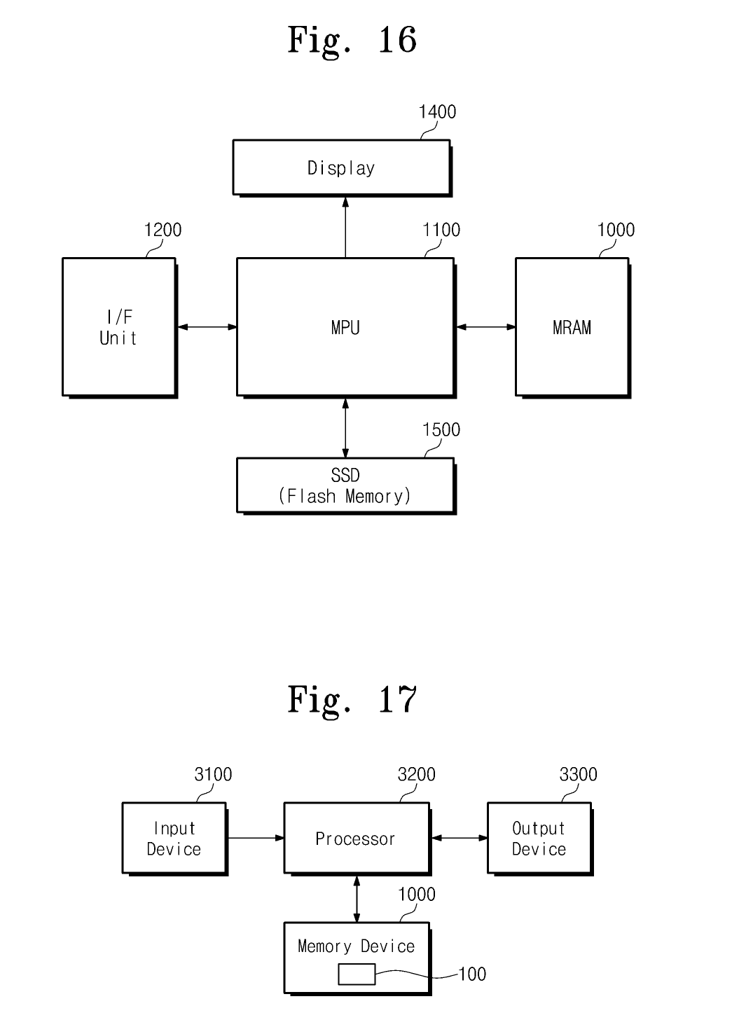

FIG. 16 is a block diagram schematically illustrating a portable electronic device according to certain embodiments.

Referring to FIG. 16, a portable electronic device (e.g., a notebook computer) includes a micro processing unit (MPU) 1100, a display 1400, an interface unit 1200, an MRAM 1000, and a solid state drive (SSD) 1500.

In some cases, the MPU 1100, the MRAM 1000 and the SSD 1500 are integrated or packed in a chip. That is, the MRAM 1000 and the SSD 150 are embedded in the portable electronic device.

If the mobile device is a portable communications device, the interface unit 1200 is connected to a modem and transceiver block which is configured to perform a communication data transmitting and receiving function and a data modulating and demodulating function.

The MPU 1100 controls an overall operation of the portable electronic device according to a given program.

The MRAM 1000 is connected to the MPU 1100 through a system bus, and functions as a buffer memory or a main memory of the MPU 1100. The MRAM 1000 has a memory cell array arrangement structure as described above with reference to various embodiments. Thus, an overhead of a chip size is small and a source line is driven using a relatively low level. As a result, the performance of the portable electronic device is improved and a cost needed to implement a system is reduced.

The SSD 1500 may include a flash memory such as a NOR or NAND flash memory.

The display unit 1400 has, for example, a liquid crystal having a backlight, a liquid crystal having an LED light source, or a touch screen (e.g., OLED). The display unit 1400 may be an output device for displaying images (e.g., characters, numbers, pictures, etc.) in color.

The portable electronic device may be connected with an external communication device through a separate interface. The communication device may be a DVD player, a computer, a set top box (STB), a game machine, a digital camcorder, or the like.

Although not shown in FIG. 16, the portable electronic device may further include an application chipset, a camera image processor (CIS), a mobile DRAM, and so on.

An MRAM (1000) chip or a flash memory chip may be packed independently or using various packages. For example, a chip may be packed by a package such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), or the like.

In FIG. 16, there is described an embodiment where a flash memory is used. However, a variety of nonvolatile storages may be used.

The nonvolatile storage may store data information having various data formats such as a text, a graphic, a software code, and so on.

The nonvolatile storage may be formed of, for example, EEPROM (Electrically Erasable Programmable Read-Only Memory), flash memory, MRAM (Magnetic RAM), STT-MRAM (Spin-Transfer Torque MRAM), CBRAM (Conductive bridging RAM), FeRAM (Ferroelectric RAM), PRAM (Phase change RAM) called OUM (Ovonic Unified Memory), RRAM or ReRAM (Resistive RAM), nanotube RRAM, PoRAM (Polymer RAM), NFGM (Nano Floating Gate Memory), holographic memory, molecular electronics memory device), or insulator resistance change memory.

Main blocks of a portable telephone (e.g., a smart phone) including an MRAM may include an antenna ATN, an analog front end block AFE, analog-to-digital converters ADC1 and ADC2, digital-to-analog converters DAC1 and DAC2, a baseband block BBD, a speaker SPK, a liquid crystal monitor LCD, a microphone MIK, and an input key KEY.

The analog front end block AFE may be formed of an antenna switch, a band pass filter, various amplifiers, a power amplifier, a phase locked loop, a voltage controlled oscillator, an orthogonal demodulator, an orthogonal modulator, etc. and transmits and receives radio waves. The baseband block BBD includes a signal processing circuit SGC, a central processing unit CPU, and an MRAM including a memory cell array structure according to certain embodiments.

When an image including voice and character information is received, a radio wave input from the antenna ATN is provided to the analog-to-digital converter ADC1 through the analog front end block AFE for waveform equalization and analog-to-digital conversion. An output signal of the analog-to-digital converter ADC1 is provided to the signal processing circuit SGC of the baseband block BBD for voice and image processing. A voice signal is transferred to the speaker SPK through the digital-to-analog converter DAC2, and an image signal is transferred to the liquid crystal monitor. In the event that a voice signal is transmitted, a signal input through the microphone MIK is provided to the signal processing circuit SGC through the analog-to-digital converter ADC2 for voice processing. An output of the signal processing circuit SGC is transferred to the antenna ATN through the digital-to-analog converter DAC1 and the analog front end block AFE. In the event that character information is transmitted, a signal input from the input key KEY is provided to the antenna ATN through the baseband block BBD, the digital-to-analog converter DAC1 and the analog front end block AFE.

In the baseband block BBD, the MRAM according to certain embodiments, the central processing unit CPU, and the signal processing circuit SGC are connected bi-directionally. Here, the central processing unit CPU executes a control in the baseband block BBD or a control of a peripheral block (not shown) according to a signal from the input key KEY, an output of the analog-to-digital converter ADC1, and an output of the signal processing circuit SGC. For example, the central processing unit CPU writes or reads information (e.g., dial numbers, abbreviated numbers, etc.) in or from the MRAM.

As another example, the central processing unit CPU controls the signal processing circuit SGC according to an output signal of the signal processing circuit SGC and an output signal of the analog-to-digital converter ADC1, and writes or reads a program for signal processing in or from the MRAM. The MRAM of the embodiments disclosed herein may be used as a buffer that temporarily stores image signals provided from the signal processing circuit SGC and outputs the temporarily stored image signals to the liquid crystal monitor.

The number of parts of the portable telephone system may be reduced by applying the MRAM of the embodiments disclosed herein to a programmable ROM using a flash memory and main, cache and image memories using an SRAM. Also, it is possible to implement a light and small portable telephone. In the MRAM of the various embodiments disclosed herein, since the degree of integration is excellent and reference cells are implemented by normal memory cells, the performance of the portable telephone is improved.

Another application of the MRAM of the embodiments disclosed herein is a system LSI where a plurality of components and the MRAM of the embodiments disclosed herein are formed on a chip. For example, parts become more light and smaller by mounting a system LSI where the baseband block BBD is formed on a chip, on the portable telephone. Also, since a data processing speed is improved by the system LSI, a processing capacity of the portable telephone is improved.

FIG. 17 is a block diagram schematically illustrating an electronic system according to certain embodiments.

Referring to FIG. 17, an electronic system includes an input device 3100, an output device 3300, a processor 3200, and a memory device 1000.

The memory device 1000 includes an MRAM 100 having the memory cell array structure shown in FIG. 1 or 8, so that an overhead of a chip size is reduced and a power is saved. Also, note that a semiconductor device including the MRAM 100 is integrated with one of the input device 3100, the output device 3300, and the processor 3200.

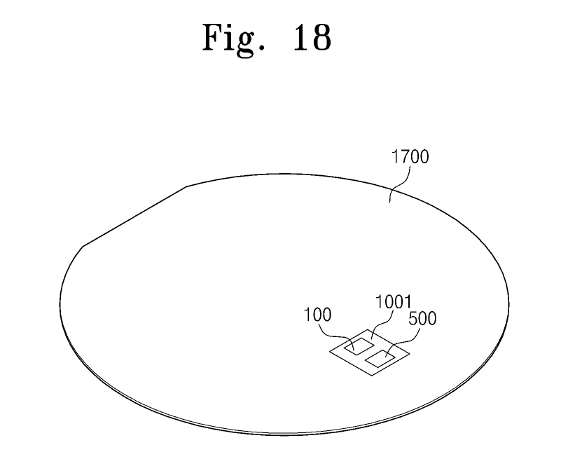

FIG. 18 is a diagram illustrating a semiconductor wafer according to certain embodiments.

Referring to FIG. 18, a memory device 100 such as the above-described MRAM is fabricated in a chip 1001 on a semiconductor wafer 1700 together with another electronic device 500. It is understood that the memory device 100 is fabricated on another semiconductor substrate.

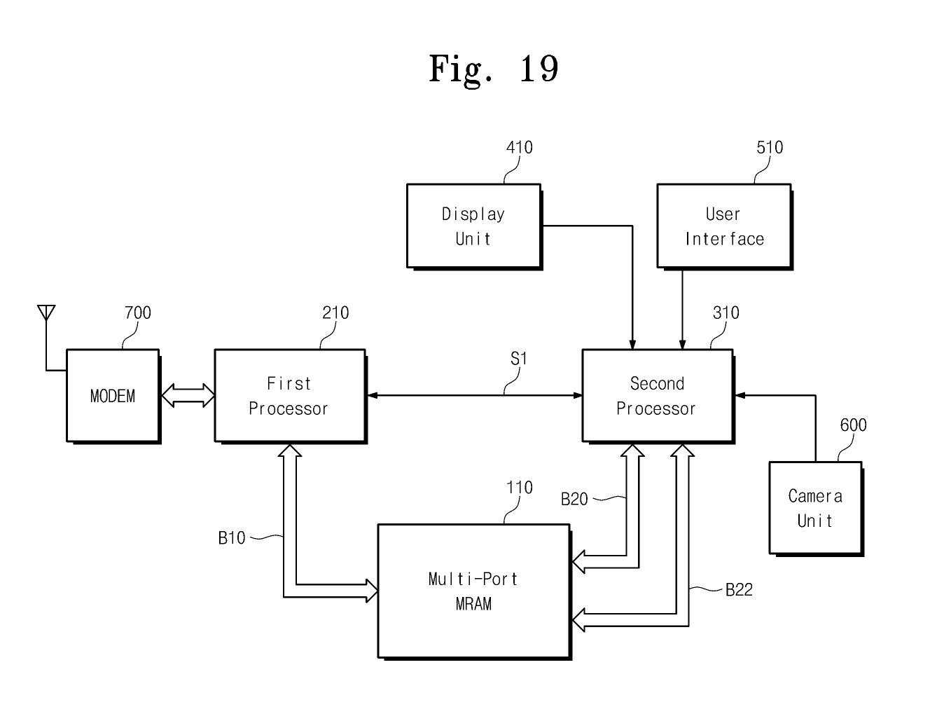

FIG. 19 is a block diagram schematically illustrating a mobile device according to certain embodiments.

Referring to FIG. 19, a mobile device includes a multi-port MRAM 110, a first processor 210, a second processor 310, a display unit 410, a user interface 510, a camera unit 600, and a modem 700.

The multi-port MRAM 110 having memory cell array structures according to embodiments includes three ports connected to first, second, and third buses B10, B20, and B22, and is connected to the first and second processors 210 and 310.

A first port of the multi-port MRAM 110 is connected to the first processor 210 being a baseband processor through the first bus B10, and a second port thereof is connected to the second processor 310 being an application processor through the second bus B20. Also, a third port of the multi-port MRAM 110 is connected to the second processor 310 through the third bus B22.

Thus, one multi-port MRAM 110 may be a memory device that replaces a storage memory and two DRAMs.

The multi-port MRAM 110 shown in FIG. 19 may include three ports and perform roles of a DRAM and a flash memory.

In this case, the multi-port MRAM 110 reduces an overhead of a chip size and drives a pseudo source line with a low power, so that the performance of a mobile device including the multi-port MRAM 110 is improved and the reliability of a circuit is improved.

An interface of the first bus B10 and an interface of the third bus B22 may be a volatile memory interface such as a DRAM interface.

An interface of the second bus B20 may be a nonvolatile memory interface such as a NAND flash interface.

In some cases, the first and second processors 210 and 310 and the multi-port MRAM 110 may be integrated or packaged in a chip. In this case, the multi-port MRAM 110 may be embedded in the mobile device.

In the event that the mobile device is a handheld communications device, the first processor 210 may be connected to the modem 700 that transmits and receives communications data and modulates and demodulates data.

A NOR or NAND flash memory may be additionally connected to the first processor 210 or the second processor 310 to store mass information.

The display unit 410 has, for example, a liquid crystal having a backlight, a liquid crystal having an LED light source, or a touch screen (e.g., OLED). The display unit 410 may be an output device for displaying images (e.g., characters, numbers, pictures, etc.) in color.

One embodiment describes that the mobile device is a mobile communications device. In some cases, the mobile device may be used as a smart card by adding or removing components to or from the mobile device.

The mobile device may be connected to an external communications device through a separate interface. The communications device may be a DVD player, a computer, a set top box (STB), a game machine, a digital camcorder, or the like.

The camera unit 600 may include a camera image processor (CIS), and is connected to the second processor 310.

Although not shown in FIG. 19, the mobile device may further include an application chipset, a mobile DRAM, and so on.

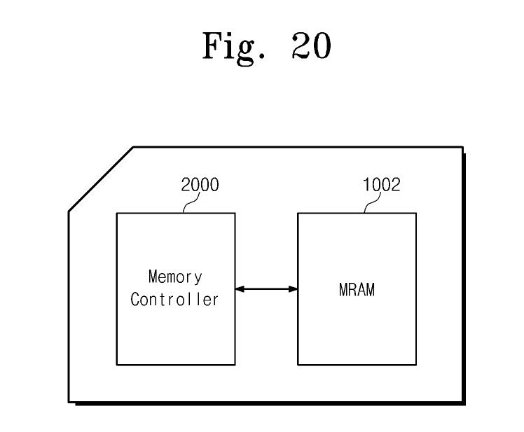

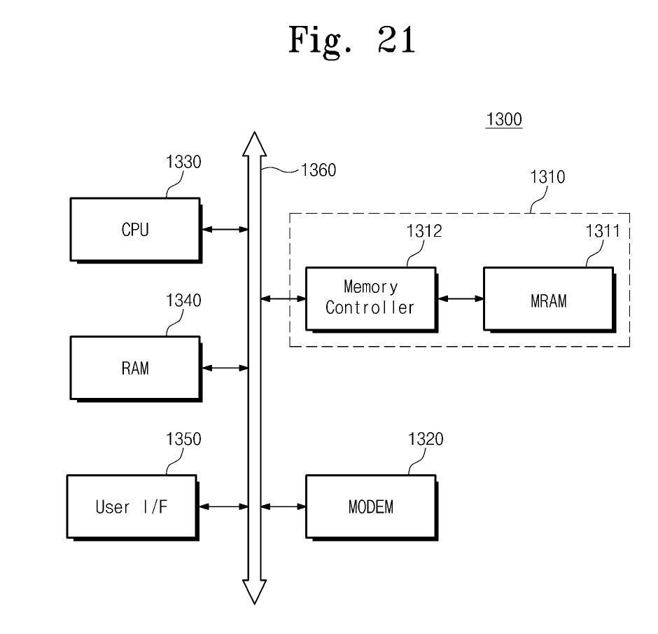

FIG. 20 is a block diagram schematically illustrating a memory card according to certain embodiments.

Referring to FIG. 20, a memory card includes a memory controller 2000 and an MRAM 1002. Here, the MRAM 1002 has a memory cell array structure according to embodiments disclosed herein. Thus, a cost of the memory card is reduced and the performance of the memory card is improved.

The memory controller 2000 writes data needed for an operation of the memory card to a selected memory cell of the MRAM 1002. The MRAM 1002 reads out data stored in a selected memory cell in response to an input of a read command from the memory controller 2000.

FIG. 21 is a block diagram schematically illustrating a computing device according to certain embodiments.

Referring to FIG. 21, a computing device 1300 includes a memory system 1310 including an MRAM 1311. The computing device 1300 may include an information processing device or a computer. For example, the computing device includes the memory system 1310, a MODEM 1320, a CPU 1330, a RAM 1340, and a user interface 1350 that are electrically connected to a system bus 1360. Data processed by the CPU 1330 or data input from an external device may be stored in the memory system 1310.

The computing device 1300 may further comprise a solid state disk, a camera image sensor, an application chipset, and so on. For example, the memory system 1300 may be formed of a solid state drive (SSD). In this case, the computing device 1300 may store mass data at the memory system 1310 stably and reliably.

The MRAM 1311 that forms the memory system 1310 together with a memory controller 1312 has the memory cell array structure (or, architecture) described with reference to FIG. 1 or 8. Thus, the performance of the computing device 1300 is improved.

While the disclosure has been described with reference to exemplary embodiments, it will be apparent to those skilled in the art that various changes and modifications may be made without departing from the spirit and scope of the present invention. Therefore, it should be understood that the above embodiments are not limiting, but illustrative.

For example, changes or modification on a pseudo separate source line of a memory cell array may be made by changing circuit components of drawings or adding or subtracting components without departing from the spirit and scope of the present invention. Also, the disclosed embodiments are mainly described using a memory system including an MRAM. However, the inventive concept is applicable to other semiconductor memory devices that sense a current difference without a current mirroring operation.

1. A memory cell array of a nonvolatile semiconductor memory device comprising:
a first memory cell including a first variable resistance element and a first access transistor connected to each other, and having a first node connected to a first bit line and one end of the first variable resistance element and a second node connected to a second bit line and one end of the first access transistor; and
a second memory cell including a second variable resistance element and a second access transistor connected to each other, and having a first node connected to the second bit line and one end of the second variable resistance element and a second node connected to one end of the second access transistor,
wherein the first and second access transistors are connected to first and second word lines, respectively.

2. The memory cell array of claim 1, wherein each of the first and second memory cells is a spin transfer torque magneto resistive random access memory (STT-MRAM) cell and each of the first and second variable resistance elements is a magnetic tunnel junction (MTJ) element.

3. The memory cell array of claim 2, wherein the second node of the second memory cell is a node connected to the first bit line.

4. The memory cell array of claim 3, wherein when the first memory cell is selected, a read current flows from the first bit line to the second bit line, and
wherein when the second memory cell is selected, a read current flows from the second bit line to the first bit line.

5. The memory cell array of claim 4, wherein the first and second bit lines extend in a first direction, and are spaced apart in a second direction perpendicular to the first direction, and
wherein the first and second memory cells are arranged diagonally with respect to each other and the first and second directions.

6. The memory cell array of claim 2, wherein the second node of the second memory cell is a node connected to a third bit line.

7. The memory cell array of claim 6, wherein when the first memory cell is selected a read current flows from the first bit line to the second bit line, and
wherein when the second memory cell is selected a read current flows from the second bit line to the third bit line.

8. The memory cell array of claim 7, wherein when the second memory cell is selected the first bit line acts as a dummy bit line not participating in an access operation.

9. The memory cell array of claim 7, further comprising:
third through nth memory cells each including a respective MTJ and a respective access transistor connected to each other, and having a first node connected to a respective bit line and one end of the respective MTJ, and a second node connected to a respective next bit line and one end of the respective access transistor, n being a natural number greater than 2,
wherein when the first memory cell is selected, a bit line connected to the nth memory cell acts as a dummy bit line not participating in an access operation.

10. A memory cell array of a nonvolatile semiconductor memory device, the memory cell array comprising:
a first memory cell including a first variable resistance element and a first access transistor connected to each other, one end of the first variable resistance element connected to a first bit line, a first source/drain of the first access transistor connected to a second bit line, and a gate of the first access transistor connected to a first word line; and
a second memory cell including a second variable resistance element and a second access transistor connected to each other, one end of the second variable resistance element connected to the second bit line, and a gate of the second access transistor connected to a second word line.

11. The memory cell array of claim 10, wherein a source/drain of the second access transistor is connected to the first bit line.

12. The memory cell array of claim 11, wherein the first memory cell further includes a first dummy transistor having a first source/drain connected to the first variable resistance element and the first access transistor, and a second source/drain connected to the first bit line, and
wherein the second memory cell further includes a second dummy transistor having a first source/drain connected to the second variable resistance element and the second access transistor, and a second source/drain connected to the second bit line.

13. The memory cell array of claim 11, wherein when the first memory cell is selected a read current flows from the first bit line to the second bit line, and
wherein when the second memory cell is selected a read current flows from the second bit line to the first bit line.

14. The memory cell array of claim 10, wherein one end of the second access transistor is connected to a third bit line.

15. The memory cell array of claim 14, wherein the first memory cell further includes a first dummy transistor having a first source/drain connected to the first variable resistance element and the first access transistor, and a second source/drain connected to the first bit line, and
wherein the second memory cell further includes a second dummy transistor having a first source/drain connected to the second variable resistance element and the second access transistor, and a second source/drain connected to the second bit line.

16. The memory cell array of claim 14, wherein when the first memory cell is selected a read current flows from the first bit line to the second bit line, and
wherein when the second memory cell is selected a read current flows from the second bit line to the third bit line.

17-26. (canceled)

27. A memory cell array of a nonvolatile semiconductor memory device, the memory cell array comprising:
a first memory cell including a first variable resistance element and a first access transistor connected to each other, a first source/drain of the first access transistor connected to a first bit line, a gate of the first access transistor connected to receive a first word line signal; and
a second memory cell including a second variable resistance element and a second access transistor connected to each other, one end of the second variable resistance element connected to the first bit line, a gate of the second access transistor connected to receive a second word line signal,
wherein when the first access transistor is selected a read current flows from the first variable resistance element to the first bit line, and
wherein when the second access transistor is selected a read current flows from the first bit line to the second variable resistance element.

28. The memory cell array of claim 27, wherein one end of the first variable resistance element and a first source/drain of the second access transistor are connected to a second bit line,
wherein when the first access transistor is selected the read current flows from the second bit line to the first bit line, and
wherein when the second access transistor is selected the read current flows from the first bit line to the second bit line.

29. The memory cell array of claim 27, wherein one end of the first variable resistance element is connected to a second bit line,
wherein a first source/drain of the second access transistor is connected to a third bit line,
wherein when the first access transistor is selected the read current flows from the second bit line to the first bit line, and
wherein when the second access transistor is selected the read current flows from the first bit line to the third bit line.

30. The memory cell array of claim 27, further comprising:
first and second reference memory cells,
wherein each of the first and second reference memory cells has the same type as the variable resistance element of each of the first and second memory cells, and wherein the first reference memory cell has a resistance value of a variable resistance element having a first resistance state and the second reference memory cell has a resistance value of a variable resistance element having a second resistance state different from the first resistance state.
